(19) United States
(12) Patent Application Publication
(10) Pub. No.: US 2023/0086826 A1
(43) Pub. Date: Mar. 23, 2023

(54) Method, Apparatuses and System for Correcting an Influence of an Interference Effect on a Gradient System

(71) Applicant: Siemens Healthcare GmbH, Erlangen (DE)

(72) Inventors: Manuel Stich, Parkstein (DE); Julian Richter, Unterpleichfeld (DE); Richard Dederichs, Herzogenaurach (DE)

(73) Assignee: Siemens Healthcare GmbH, Erlangen (DE)

(21) Appl. No.: 17/944,381

(22) Filed: Sep. 14, 2022

(30) Foreign Application Priority Data
Sep. 15, 2021 (EP) 21196773.2

(51) Int. Cl. G01R 33/385; A61B 90/00

(52) U.S. Cl. CPC G01R 33/3852; A61B 90/08

(57) ABSTRACT

In a method for correcting an influence of an interference effect on a gradient system of a MR apparatus during a MR scan, a gradient pulse is emitted by an amplifier of the gradient system, a gradient sequence is established, an output signal of the amplifier is captured for the gradient pulse, a transfer function is established, and an output signal of the amplifier is established such that the gradient system provides an expected gradient sequence.

### CROSS REFERENCE TO RELATED APPLICATIONS

This patent application claims priority to European Patent Application No. 21196773.2, filed Sep. 15, 2021, which is incorporated herein by reference in its entirety.

### BACKGROUND

### Field

The disclosure relates to a method for correcting an influence of an interference effect on a gradient system of a magnetic resonance apparatus during a magnetic resonance scan. The disclosure also relates to a magnetic resonance apparatus and a magnetic resonance system with a correcting facility.

### Related Art

In a magnetic resonance system, typically an examination object is exposed, with the aid of a main field magnet system, to a main magnetic field with a magnetic field strength of between 0.5 tesla and 7 tesla. On application of the main magnetic field, atomic nuclei in the examination object become aligned with a non-decaying nuclear magnetic dipole moment, often also called spin, along the main magnetic field. Such a collective behavior of the spin is also designated “magnetization” on a macroscopic scale. The magnetization is the vector sum of all the microscopic magnetic moments at a particular location in the object.

In addition to the main magnetic field, with the aid of a gradient system, a magnetic field gradient is applied, with which the magnetic resonance frequency (Larmor frequency) is determined at the respective location. Using a radio frequency transmitter, by means of suitable antenna facilities, radio frequency excitation signals or radio frequency fields (RF pulses) are then emitted, which is intended to cause the spins of particular atomic nuclei that are excited by way of this radio frequency field into resonance (i.e. at the Larmor frequency present at the respective location) to be tilted through a defined flip angle relative to the magnetic field lines of the main magnetic field. If such an RF pulse acts upon spins that have already been excited, then these can be tilted into a different angular position or even folded back into a starting state parallel to the main magnetic field. On relaxation of the excited spins, radio frequency signals known as magnetic resonance signals are emitted in a resonant manner. These magnetic resonance signals can be received by means of suitable receiving antennae (antenna facilities, also known as magnetic resonance coils or receiving coils) and subsequently demodulated, digitized and further processed as so-called “raw data”. The receiving of the magnetic resonance signals takes place in a spatial frequency domain, the so-called “k-space”, wherein during a magnetic resonance scan, for example, a slice of the k-space is passed through over time along a “gradient trajectory” (also called “k-space trajectory”) defined by the switching of the gradient pulses. Therein, the RF pulses are emitted in a temporally suitable coordinated manner. Finally, from the acquired raw data, by means of a two-dimensional Fourier transform, image data from the examination object can be reconstructed. Alternatively, three-dimensional volumes can meanwhile also be defined, excited and read out, wherein the raw data is again sorted, after further processing steps, into a three-dimensional k-space. A reconstruction of three-dimensional image data can accordingly take place by means of a three-dimensional Fourier transform.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a magnetic resonance system according to an exemplary embodiment of the present disclosure.

FIG. 2 is a schematic representation of an influence of interference effects in a magnetic resonance scan according to an exemplary embodiment of the present disclosure.

FIG. 3 is a graphical representation which illustrates a variable temperature influence on a gradient system of a magnetic resonance system according to an exemplary embodiment of the present disclosure.

FIG. 4 is a schematic representation of a principle of an adjustment of an input signal of an amplifier using a correcting facility according to an exemplary embodiment of the present disclosure.

FIG. 5 is a graphical representation illustrating an establishment of a gradient system transfer function dependent upon a plurality of gradient pulses according to an exemplary embodiment of the present disclosure.

FIG. 6 is a flowchart of a method according to an exemplary embodiment of the present disclosure.

The exemplary embodiments of the present disclosure will be described with reference to the accompanying drawings. Elements, features and components that are identical, functionally identical and have the same effect are — insofar as is not stated otherwise — respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

For controlling a magnetic resonance system in the execution of a magnetic resonance scan, particular sequences of RF pulses and gradient pulses — so-called pulse sequences — may be used. The pulse sequences can be played out in different spatial directions and/or read-out time windows, during which the receiving antennae are switched to receive and the magnetic resonance signals are received.

The gradient pulses may be defined by a gradient amplitude a gradient pulse duration and an edge steepness and/or the first derivative of the pulse shape dG/dt of the gradient pulse (“slew rate”). Since the gradient system has a maximum loading capacity, a strength and the slew rate of the gradient pulse is fundamentally limited.

With the aid of a so-called scan protocol, the aforementioned pulse sequences for a desired examination, for example, a particular contrast of the calculated images, may be parameterized in advance. The scan protocol can also contain further control data for the magnetic resonance scan. In principle, there is a plurality of possibilities as to how the pulse sequences can be constructed in order to obtain desired image data from the examination object.

In the following, “magnetic resonance recordings” should be understood as image data of an interior of an examination object generated with the aid of a magnetic resonance apparatus controlled as part of the method, but also parameter maps which represent a spatial or temporal distribution of particular parameter values within the examination object and can be generated, for example, from the image data. A “recording” of magnetic resonance image data should be understood therein to be the performance of a magnetic resonance scan with the aid of a magnetic resonance system.

As described above, during the magnetic resonance scan, firstly magnetic resonance signals may be measured, their amplitudes being interpreted as Fourier transforms of the image data in the k-space. The k-space can therein be regarded as a spatial frequency domain of a density distribution of the magnetic moments in a region being examined, in which magnetic resonance signals are captured. If the k-space has been sufficiently exactly sampled, then by means of a (for slice-wise sampling, two-dimensional) Fourier transform, the spatial distribution of the density of the magnetic moments can be obtained. The k-space may be sampled line-by-line along a Cartesian grid. Besides this, other sampling patterns are however also conceivable.

In the magnetic resonance scan, the accuracy of the playing out of the gradient pulses by way of the gradient system has a strong influence on the quality of captured image data. Apart from pulse sequences with Cartesian trajectories of the gradient pulses, pulse sequences with radial or spiral-shaped trajectories can also be used. In addition, so-called single-shot EPI sequences may also be used for magnetic resonance scans. The latter sequences place greater demands on the temporal accuracy of the magnetic field gradients. The causes of deviations between played-out gradient pulses and the expected gradient pulses lie, for example, in the occurrence of eddy currents, time-tuning and amplification errors as well as field fluctuations, which are caused by mechanical vibrations after switching-over of magnetic field gradients, but also a thermal variation and/or a non-linear behavior of hardware components such as, for example, an amplifier and/or a gradient coil of the gradient system. Such interference effects lead to gradient sequences that deviate from the expected gradient sequences. This deviation leads to errors in the establishment of the k-space trajectory, errors in the acquired signal and finally to artifacts in the image data.

If the deviations are exactly known, then an actual k-space trajectory can be established and used for the reconstruction of image data. Alternatively, the actual k-space trajectory can also be measured. Typically, a correction of gradient pulses takes place for a specific gradient system state at a single temperature. For example, a gradient system transfer function is established once for the room temperature and is then used for the entire imaging sequence without taking account of a temperature change during the imaging.

The single, static gradient correction is based upon a technique which makes use of a transfer function such as a Gradient Impulse Response Function (GIRF) or a Gradient System Transfer Function (GSTF) according to equation (1) to correct deviations. Therein, F is the Fourier transform, f is frequency and t is time.

$$G S T F \left(f\right) = F \left\{G I R F \left(t\right)\right\}$$

Herein, linear and time-invariant characteristics of the dynamic gradient system may be used to correct played-out gradient pulses during the image reconstruction. In one technique, the gradient impulse response function GIRF or the gradient system transfer function GSTF of the magnetic resonance system is used to correct non-Cartesian trajectories. Therein, through the use of the gradient system transfer function GSTF, in particular, a behavior of the entire gradient system can be characterized.

In a so-called post-correction, corrected gradient pulses g_{post,l}(t) may be calculated for each axis (1 = x, y, z) by means of multiplication of the Fourier transform of the nominal gradient G_{nom,l}(f) with corresponding gradient system transfer functions for a specific temperature state GSTF_{1,1}(f) and a Fourier transform into the time domain (inverse transform):

$${g}_{p o s t , l} \left(t\right) = {F}^{- 1} \left\{F \left\{{g}_{n o m , l} \left(t\right)\right)\right\} ⋅ G S T {F}_{l , l} \left(\left(f\right)\right\}$$

The value “1” represents the direction x, y, z in which an input gradient g_{nom,l}(t), also called the nominal gradient, has been played out and in which an output gradient Gᵣₑₐₗ,₁(f) is measured.

Alternatively, with a preceding correction (a so-called “pre-emphasis”), the inverse gradient impulse response function or gradient system transfer function is used. Herein, a corrected nominal gradient pulse g_{pre,l}(t) which corresponds to the desired nominal gradient pulse g_{nom,l} can be played out, so that a desired output gradient G_{real,1}(t) is achieved:

$${g}_{p r e , l} \left(t\right) = {F}^{- 1} \left\{F \left\{{g}_{n o m , l} \left(t\right)\right\} ⋅ G S T {F}_{l , l}^{- 1} \left(f\right)\right\}$$

Equations (2) and (3) show simplified corrections of the gradient pulses wherein only first order autoterms of the gradient system transfer function are used. For the sake of explanation, it should be mentioned briefly here that the gradient system transfer function also comprises terms which describe interactions between magnetic field components of different directions and higher order terms. In order to carry out a comprehensive and complete correction, all the terms of the gradient system transfer function from the 0-th to the n-th order must be used. A sufficient correction can, however, already be achieved in that mainly the 0-th order terms are used to correct the main magnetic fields (B₀ fields) and the first order terms are used to correct the magnetic field gradients. During the determination of the gradient system transfer function, the gradient system should be checked with a broad frequency spectrum. Ideally, a Dirac impulse function is used as the test gradient function in order to achieve a coverage of all the frequencies.

The gradient pulses which are played out by the gradient system of the magnetic resonance apparatus are typically measured in small dynamic field probes with which a phase development or a phase signal can be determined. The phase signal is based upon a raw signal, that is, the signal that is measured by the receiving antennae. Only the phase of the raw signal is further processed. The magnitude is left out of consideration. From the phase signal, the gradient can be determined.

The correction of gradient pulses is thus already known. However, all the known techniques are restricted to a correction of k-space data downstream of the acquisition of magnetic resonance signals or to a correction of interference effects constantly occurring during the sequence of a magnetic resonance recording. A compensation of a dynamic, in particular non-linear, behavior of components of the gradient system of the magnetic resonance apparatus during magnetic resonance scans has so far not been considered.

An object of the present disclosure is to provide a method for the correction of deviations between played-out gradient pulses of expected gradient sequences during a magnetic resonance scan.

In an exemplary embodiment, the method according to the disclosure for correcting an influence of an interference effect on a gradient system on a gradient system of a magnetic resonance apparatus during a magnetic resonance scan may include the following steps:
emitting a gradient pulse g_{ref}(t) by means of an amplifier of the gradient system,
capturing a gradient sequence gᵣₑₐₗ(t) by means of a magnetic field measurement in an examination region of the magnetic resonance apparatus,
capturing an output signal iₒᵤt(t) of the amplifier for the gradient pulse g_{ref}(t),
establishing a gradient system transfer function (GSTF, GIRF) dependent upon the captured gradient sequence gᵣₑₐₗ(t) and the captured output signal iₒᵤt(t) of the amplifier,
establishing an output signal i_{cor}(t) of the amplifier with which the gradient system provides an expected gradient sequence gₙₒₘ(t), dependent upon the established gradient system transfer function (GSTF, GIRF).

In one step of the method according to the disclosure, at least one gradient pulse g_{ref}(t) may be emitted. The gradient pulse g_{ref}(t) can represent part of a pulse sequence which can comprise one or more gradient pulses, but also one or more RF pulses. The gradient pulse can represent, for example, a regular gradient pulse of the pulse sequence that is needed for performing a magnetic resonance scan of an examination object. A regular gradient pulse can comprise, for example, an imaging gradient or a diffusion gradient. In an exemplary embodiment, an imaging gradient may serve for localization of an influence of an RF pulse. However, the gradient pulse can also be emitted exclusively as a test gradient pulse, in particular in cases in which other gradient pulses of a pulse sequence are unsuitable as a test gradient pulse. Furthermore, the gradient pulse can take on a double function as a test gradient pulse and as a regular gradient pulse in a pulse sequence. A test gradient pulse can be, in particular, a gradient pulse which is used directly or indirectly for correcting an influence of an interference effect on the gradient system of the magnetic resonance apparatus during a magnetic resonance scan.

Interference effects such as the occurrence of eddy currents, time-tuning and amplification errors, field fluctuations, variable temperature influences and/or the non-linear behavior of hardware components such as, for example, the amplifier and/or the gradient coils of the gradient system, can cause a deviation between played-out gradient coils and expected gradient sequences.

In an exemplary embodiment, a magnetic resonance scan may represent an imaging examination of an examination object, in particular a patient. It is conceivable that during the magnetic resonance scan, two-dimensional, three-dimensional and/or time-dependent three-dimensional image data of the examination object is captured. However, it is equally conceivable that a magnetic resonance scan is carried out for a calibration and/or a test of the magnetic resonance apparatus, but also a magnetic resonance spectroscopic scan. Herein, the examination object can comprise, for example, a reference object, a phantom and/or a field probe which interact in a predetermined manner with a pulse sequence played out during the magnetic resonance scan. In one embodiment, the execution of the magnetic resonance scan comprises the aim of characterizing deviations between played-out gradient pulses and expected gradient sequences by means of the method according to the disclosure.

In an exemplary embodiment, the emitted gradient pulse g_{ref}(t) has a triangular form, a rectangular form or a trapezoidal form. Gradient pulses formed in this manner cover a broad frequency spectrum and are therefore particularly suitable for a correction of trajectories in the entire k-space. However, it is also conceivable that the emitted gradient pulse has a radial and/or spiral trajectory.

In an exemplary embodiment, an expected or nominal gradient sequence gₙₒₘ(t) is associated with the emitted gradient pulse g_{ref}(t). The expected gradient sequence can match the emitted gradient pulse if no interference effects occur in the gradient system. The emitted gradient pulse can be a “nominal gradient pulse” in this case, which is characterized by the nominal field strength values which are to be expected on emission of a gradient pulse. In a real magnetic resonance scan, however, the nominal field strength values deviate, due to dynamic interference influences, from the real field strength values of the gradient pulse. This deviation can be established by way of a corresponding measurement of the gradient sequence gᵣₑₐₗ(t).

In one step, the gradient sequence gᵣₑₐₗ(t) is captured by means of a magnetic field measurement in an examination region of the magnetic resonance apparatus. The captured gradient sequence consists, in particular, of actual field strength values which are generated in the examination region by the emitted gradient pulse g_{ref}(t). The capturing of the gradient sequence can take place, for example, by means of a magnetometer or a field camera. The magnetometer or the field camera can be introduced into the examination region of the magnetic resonance apparatus for the capturing of the gradient sequence. For this purpose, the field camera can have a signal connection to an input interface of the magnetic resonance apparatus and can transfer the captured gradient sequence by means of the signal connection to the input interface. It is further conceivable that the gradient sequence is captured by a radio frequency receiving antenna of the magnetic resonance apparatus. For this purpose, a field probe or a volume of a reference substance, such as for example, water or oil can be introduced into the examination region of the magnetic resonance apparatus and can be excited by means of a predetermined RF pulse. A magnetic resonance signal of the field probe or reference substance received by means of a radio frequency receiving antenna of the magnetic resonance apparatus can subsequently be analyzed in order to obtain an item of information via a property of the emitted gradient pulse. The analysis of the received magnetic resonance signal can comprise, in particular, a comparison of an expected magnetic resonance signal of the field probe or the reference substance with the received magnetic resonance signal.

A gradient pulse can be understood to be a magnetic field strength or a time-dependent magnetic field strength sequence which is to be provided by means of the gradient system. A gradient sequence, however, can be characterized by a field strength captured by measurement or a captured time-dependent field strength pattern. The gradient sequence is therefore to be understood, in particular, as an actual magnetic field gradient which becomes established in the examination region by way of the emission of the gradient pulse. As a result of an influence of the aforementioned interference effects, the gradient sequence can deviate from the gradient pulse.

In a further step, an output signal iₒᵤt(t) of the amplifier for the gradient pulse g_{ref}(t) is captured. The output signal iₒᵤt(t) of the amplifier can be, in particular, an electric current which is fed by the amplifier into a gradient coil of the gradient system. In an exemplary embodiment, the capturing of the output signal of the amplifier takes place while the gradient pulse g_{ref}(t) is emitted by a gradient coil of the gradient system. The output signal of the amplifier can therein be captured by means of a suitable measuring device, such as, for example, a current probe, a Rogowski coil, a voltage measuring device, but also a measuring or current transformer. In an exemplary embodiment, the captured output signal of the amplifier is transferred to the input interface of the magnetic resonance apparatus. But it is equally conceivable that the output signal of the amplifier is established dependent upon a desired measuring variable and/or with the aid of a known characteristic curve or operating characteristic of the amplifier. The expression amplifier is therein to be understood, in particular, as a gradient amplifier which raises and/or transforms a signal with a low signal level (input signal of the amplifier) into a signal with a high level (output signal of the amplifier). The output signal of the amplifier can be fed to a gradient coil of the gradient system which accordingly generates a magnetic field gradient in the examination region (emitted gradient pulse). In an exemplary embodiment, the gradient system has at least three gradient coils which are configured to provide magnetic field gradients aligned orthogonally to one another.

In one step of the method according to the disclosure, dependent upon the captured gradient sequence gᵣₑₐₗ(t) and the captured output signal iₒᵤt(t) of the amplifier, a gradient system transfer function (GSTF, GIRF) is established. The establishing of the gradient system transfer function can therein take place by means of a computer unit of the magnetic resonance apparatus which has a signal connection to the input interface. For the sake of simplification, the expressions GSTF and GIRF are subsumed below under the expression gradient system transfer function, since the two functions can be converted into one another by means of equation (1).

The gradient system transfer function is typically determined dependent upon the quotient of a gradient Gᵣₑₐₗ(f) played out by means of the amplifier and an expected or nominal gradient Gₙₒₘ(f) in accordance with equation (4). This type of gradient system transfer function represents a so-called gradient input GSTF with which the nominal input gradient Gₙₒₘ(f) is called upon for the determination of the gradient system transfer function.

$$G S T F = \frac{{G}_{r e a l} \left(f\right)}{{G}_{n o m} \left(f\right)}$$

By contrast, in the method according to the disclosure, the gradient system transfer function is established dependent upon the captured gradient sequence gᵣₑₐₗ(t) and the captured output signal iₒᵤt(t) of the amplifier as per equation (5). For this purpose, the captured output signal iₒᵤt(t) of the amplifier and the captured gradient sequence gᵣₑₐₗ(t) can initially be transformed by means of a Fourier transform into the frequency domains (Iₒᵤₜ(f), Gᵣₑₐₗ(f)).

$$G S T F = \frac{{G}_{r e a l} \left(f\right)}{{I}_{o u t} \left(f\right)}$$

In an exemplary embodiment, the establishing of the gradient system transfer function GSTF takes place using a plurality of different gradient pulses to cover a broad frequency spectrum. The frequency spectrum covered can comprise, for example, a frequency range between -20 kHz and 20 kHz, in particular between -10 kHz and 10 kHz.

In a further step of the method according to the disclosure, an output signal i_{cor}(t) of the amplifier with which the gradient system provides an expected gradient sequence (gₙₒₘ(t)), is established dependent upon the established gradient system transfer function (GSTF, GIRF). In an exemplary embodiment, the establishing of the output signal i_{cor}(t) of the amplifier is carried out by means of the computer unit of the magnetic resonance apparatus. In an exemplary embodiment, the computer unit has a signal connection to the input interface. As described above, the input interface can be configured to receive the gradient sequence and the output signal of the amplifier and, by means of the signal connection, to transfer them to the computer unit. The signal connection can therein be configured wirelessly or cable-bound.

By way of the method according to the disclosure, interference effects such as, for example, a non-linear operating characteristic of the amplifier and/or a variable temperature influence on the gradient system can advantageously be compensated for. Furthermore, image artifacts due to such interference effects can be reduced or prevented and a quality of captured image data can advantageously be improved. In particular, by way of the output of the input signal of the amplifier, a direct adjustment of the amplifier is made possible. In this way, a computation-intensive and/or time-consuming correction of interference effects in the reconstruction of image data can advantageously be prevented.

In an exemplary embodiment of the method according to the disclosure, the emitting of the gradient pulse g_{ref}(t) and the capturing of the gradient sequence gᵣₑₐₗ(t) take place in a repeating manner, in particular with a frequency of between one and five repetition intervals of a pulse sequence of the magnetic resonance scan.

In an exemplary embodiment, the emitting of the gradient pulse and the capturing of the gradient sequence take place repeatedly at discrete temporal intervals. It is conceivable that the repeated emitting of the gradient pulse and the capturing of the gradient sequence take place at a rate or frequency of between one and five repetition intervals of the pulse sequence of the magnetic resonance scan.

In one embodiment, a frequency of the repeated emitting of the gradient pulse and the capturing of the gradient sequence during the pulse sequence of the magnetic resonance scan is reduced to a minimum quantity. Experiments imply that relevant temperature changes during the magnetic resonance scan can be quantified by measurement after approximately five repetition intervals or only after the expiry of a duration of five repetition intervals. By way of a reduction of the frequency of the repeated emitting of the gradient pulse and the capturing of the gradient sequence, a duration for the magnetic resonance scan and/or a computation effort for the correction of interference effects can advantageously be reduced.

In an exemplary embodiment, the repeated emitting of the gradient pulse and the capturing of the gradient sequence takes place in each repetition interval. Thereby, unexpectedly rapidly occurring interference effects which affect the magnetic field gradients can advantageously also be quickly compensated for. A repetition interval can therein be understood as a duration which passes between two successive excitation pulses, in particular two successive RF pulses.

In one embodiment, the method according to the disclosure comprises the following step:
Establishing a temperature of a gradient coil of the gradient system,
wherein the establishing of the output signal i_{cor}(t) of the amplifier takes place dependent upon the temperature of the gradient coil.

The gradient coil of which the temperature is established therein matches the gradient coil which emits the gradient pulse g_{ref}(t) dependent upon the output signal iₒᵤt(t) of the amplifier. The establishing of the temperature of a gradient coil can take place, for example, by means of a temperature sensor or a plurality of temperature sensors which are positioned on the gradient system, in particular on the gradient coil. In an exemplary embodiment, the temperature sensor is mechanically connected to the gradient coil and has a thermal coupling with the gradient coil via the mechanical connection. The temperature sensor can be configured to transfer a measurement value for the temperature of the gradient coil or a signal which indicates the temperature of the gradient coil, by means of a signal connection to the computer unit of the magnetic resonance apparatus. The computer unit can correspondingly be configured to establish the output signal of the amplifier dependent upon the temperature of the gradient coil. It is equally conceivable that the temperature of the gradient coil is established dependent upon a measurement value and/or an operating characteristic of the amplifier which differ from the temperature measurement value.

According to a further embodiment, the method according to the disclosure further comprises the step:
establishing a resistance and/or an inductance of the gradient coil,
wherein the establishing of the temperature of the gradient coil takes place dependent upon the resistance and/or the inductance of the gradient coil.

In an exemplary embodiment, the temperature of the gradient coil is established dependent upon a resistance and/or an inductance of the gradient coil or the gradient coils. Aside therefrom, further measurement values can naturally also be used for establishing the temperature of the gradient coil. In an exemplary embodiment, the temperature of the gradient coil is established dependent upon a measurement resistor (shunt resistor) which is connected to a voltage measurement device. However, it is also conceivable that the temperature of the gradient coil is established dependent upon a temperature-dependent property, such as for example, a length of a reference wire, but also an inductance of the gradient coil.

In a further embodiment of the method according to the disclosure, the establishing of the temperature of the gradient coil takes place dependent upon a model and/or an intelligent algorithm.

An intelligent algorithm can comprise a use, as desired, of artificial intelligence. An artificial intelligence can be, for example, a self-learning algorithm, a neural network, a multi-layered neural network, an expert system or the like, which establishes the temperature of the gradient coil dependent upon a measurement value or a plurality of measurement values of the gradient system. It is further conceivable that the intelligent algorithm establishes the temperature of the gradient coil dependent upon a known operating characteristic of the amplifier and/or the gradient coil. The intelligent algorithm can further make use of a model of the gradient coil and/or the amplifier in order to establish the temperature of the gradient coil.

Furthermore, the temperature of the gradient coil can be determined dependent upon a model. A model can be, in particular, a simulation model, an analytical model, an empirical model and/or a model-based approach which describe or model the amplifier and/or the gradient coil.

In an exemplary embodiment, the establishing of the temperature of the gradient coil takes place dependent upon the captured output signal iₒᵤt(t) of the amplifier.

Given knowledge of the current that is fed from the amplifier into the gradient coil, the temperature can be determined very accurately dependent upon fundamental physical circumstances and/or analytical models of the gradient coil. In an exemplary embodiment, establishing the temperature of the gradient coil takes place by using a model and/or an intelligent algorithm by means of the computer unit of the magnetic resonance system. Naturally, the establishing of the temperature of the gradient coil can also include an establishing of temperatures of a plurality of gradient coils used for a pulse sequence.

By way of the establishing of the temperature of the gradient coil, the output signal of the amplifier can advantageously be established with increased accuracy. Furthermore, the output signal of the amplifier can be established in a particularly robust and/or reproducible manner dependent upon the temperature of the gradient coil, since variable temperature influences on the gradient coil can be considered.

In one embodiment, the method according to the disclosure comprises the step:

adjusting an input signal iᵢₙ(t) of the amplifier dependent upon the established output signal i_{cor}(t) of the amplifier and the captured output signal iₒᵤt(t) of the amplifier.

It is conceivable that the adjustment of the input signal of the amplifier takes place dependent upon a suitable regulator. Such a regulator can be configured, for example, to adjust the input signal of the amplifier dependent upon the established output signal of the amplifier and the captured output signal of the amplifier. The regulator can be configured, in particular, to adjust the input signal of the amplifier dependent upon a difference between the established output signal of the amplifier and the captured output signal of the amplifier.

In an exemplary embodiment, the adjustment of the input signal of the amplifier takes place in continuous or discrete time steps. For example, the adjustment of the input signal of the amplifier takes place multiple times per repetition interval, once per repetition interval, every second repetition interval, every third repetition interval or every fourth or fifth repetition interval. The adjustment of the input signal of the amplifier can take place, in particular, after every emission of a gradient pulse g_{ref}(t) and/or capturing of a gradient sequence gᵣₑₐₗ(t).

It is further conceivable that the adjustment of the input signal of the amplifier takes place in a second repetition interval dependent upon an output signal of the amplifier established in a first repetition interval or dependent upon a gradient system transfer function established in the first repetition interval. The first repetition interval and the second repetition interval can also be spaced from one another by a plurality of repetition intervals. This process is also designated “pre-emphasis”. With this process, a correction can already be undertaken when the gradient pulse is emitted in the second repetition interval, so that the image reconstruction needs no further correction of the gradient fields.

By way of an inventive adjustment of the amplifier input signal, interference effects in the gradient system can advantageously be corrected early and/or automatically.

According to a further embodiment of the method according to the disclosure, the adjustment of the input signal iᵢₙ(t) of the amplifier takes place by means of an adaptive filter, in particular, a Volterra filter, a spline filter and/or a kernel filter.

In an exemplary embodiment, the input signal of the amplifier can be adaptively adjusted by using a non-linear adaptive filter so that interference effects in the gradient system can be compensated for by means of changing the input signal of the amplifier. Herein, the input signal applied to an input of the amplifier can pass through the adaptive filter and form a so-called output sequence. This output sequence can be compared with a sequence to be formed by the adaptive filter like the established output signal i_{cor}(t) of the amplifier in order to establish a fault signal. In the event of a deviation of the output sequence from the sequence to be formed, a control algorithm of the adaptive filter can carry out a change of filter coefficients in order to minimize the error signal and to adjust the output sequence of the adaptive filter to the sequence to be formed. Therein, known methods for minimizing the squares of the errors, for example the least mean squares (LMS) algorithm or the recursive least squares (RLS) algorithm can be used.

In an exemplary embodiment, the adaptive filter comprises a Volterra LMS method in which discrete input values are replaced with different non-linear algebraic expressions, so-called Volterra series.

The adjustment of the input signal of the amplifier can also take place, for example, by direct or indirect means dependent upon an output sequence of the adaptive filter. In one embodiment, the output sequence of the adaptive filter is transferred as a control signal by means of a signal connection to the amplifier and/or a controller of the amplifier or the magnetic resonance apparatus. The output sequence can represent, in particular, the input signal of the amplifier. However, it is also conceivable that the output sequence represents a correction signal, dependent upon which the input signal of the amplifier is adjusted.

The adaptive filter can be implemented, for example, as an analogue filter or a digital filter. In an exemplary embodiment, the adaptive filter is implemented as a part of a DSP (digital signal processor), an FPGA (field programmable gate array) and/or an FPAA (field programmable analog array).

By using an adaptive filter, complex and/or non-linear interference effects of the gradient system can be compensated for in an advantageous manner.

In a further embodiment of the method according to the disclosure, the emission of the gradient pulse gₜₑₛₜ(t) comprises an emission of a plurality of gradient pulses gₜₑₛₜ,ᵢ(t), wherein the plurality of gradient pulses (g_{test,i}(t)) covers a frequency spectrum of between -20 kHz and +20 kHz, in particular between -10 kHz and +10 kHz.

In an exemplary embodiment, the capturing of the gradient sequence gᵣₑₐₗ(t) comprises a capturing of a gradient sequence for each gradient pulse of the plurality of gradient pulses. Therein, for each gradient sequence, an output signal i ₒᵤₜ(t) of the amplifier can also be captured. It is conceivable that in this way, a gradient system transfer function is established for a plurality of gradient pulses and a plurality of amplifier output currents. The gradient system transfer function can therein be characterized by an overlaying or a superposition of the plurality of captured gradient sequences and captured amplifier output currents.

By way of the establishing of the gradient system transfer function for a plurality of gradient pulses, which cover a broad frequency spectrum, interference effects in the gradient system can be corrected or compensated for in any gradient pulses that are included by the frequency spectrum.

The correcting facility according to the disclosure has an output interface which is configured to emit at least one gradient pulse g_{ref}(t). The output interface can comprise, for example, an output channel of an amplifier of a gradient system of the magnetic resonance system.

The correcting facility according to the disclosure further comprises an input interface which is configured to receive a gradient sequence gᵣₑₐₗ(t) and an output signal iₒᵤt(t) of an amplifier for the gradient pulse g_{ref}(t). In an exemplary embodiment, for this the input interface has a signal connection to a field camera, a magnetometer or a radio frequency receiving antenna. The input interface can also be configured as part of the radio frequency receiving antenna. It is further conceivable that the input interface has a signal connection with a current sensor, a voltage sensor and/or a temperature sensor. In principle, the input interface can have a signal connection to any desired sensor that is configured to capture with measuring technology a property of the gradient system according to an embodiment described above. In addition, the correcting facility according to the disclosure has a computer unit which is configured to establish a gradient system transfer function (GSTF, GIRF) dependent upon the captured gradient sequence gᵣₑₐₗ(t) and the captured output signal iₒᵤt(t) of the amplifier. The computer unit is further configured to establish an output signal i_{cor}(t) of the amplifier dependent upon the gradient system transfer function.

The correcting facility according to the disclosure is further configured to adjust an input signal iᵢₙ(t) of the amplifier dependent upon the established output signal i_{cor}(t) of the amplifier and the captured output signal iₒᵤt(t) of the amplifier. The establishing of the gradient system transfer function GSTF of the output signal i_{cor}(t) of the amplifier, but also the adjustment of the input signal iᵢₙ(t) of the amplifier can therein take place, according to an embodiment described above of the method according to the disclosure, by means of the correcting facility.

The correcting facility according to the disclosure shares the advantages of the method according to the disclosure for correcting an influence of an interference effect on a gradient system of a magnetic resonance apparatus during a magnetic resonance scan.

The magnetic resonance apparatus according to the disclosure comprises a correcting facility according to an embodiment described above, wherein the magnetic resonance apparatus is configured to adjust an input signal iᵢₙ(t) of an amplifier during a magnetic resonance scan of an examination object by means of the correcting facility, in order to provide an expected gradient pulse gₙₒₘ(t).

In particular, the magnetic resonance apparatus according to the disclosure can be configured to coordinate and carry out independently a sequence of individual method steps of a method according to the disclosure according to an embodiment described above. In this way, the adjustment of the input signal of the amplifier can advantageously be carried out reproducibly and/or automatically, dependent upon a gradient system transfer function and an established output signal of the amplifier.

The magnetic resonance system according to the disclosure comprises a main field magnet system, a radio frequency transmitting antenna, a gradient system, a radio frequency receiving antenna and a correcting facility according to an embodiment described above, as well as a controller for actuating the main field magnet system, the radio frequency transmitting antenna, the gradient system and the radio frequency receiving antenna.

By way of the provision of the magnetic resonance system according to the disclosure, the components of the magnetic resonance system according to the disclosure, such as for example, the main field magnet system, the radio frequency transmitting antenna, the gradient system, the radio frequency receiving antenna, as well as the correcting facility and the controller, can advantageously be matched to one another so that a time-efficient and/or robust execution of a method according to the disclosure in accordance with an embodiment described above is enabled.

The computer program product according to the disclosure comprises a computer program which is loadable directly into a memory storage unit of the controller of a magnetic resonance system according to the disclosure, having program portions in order to carry out all the steps of a method according to the disclosure in accordance with an embodiment described above when the computer program is executed by means of the controller of the magnetic resonance system.

In an exemplary embodiment, the correcting facility according to the disclosure can be realized in the form of software on a suitably programmable controller of a magnetic resonance system with a corresponding storage unit. A radio frequency transmitter, an output interface and a radio frequency receiver can also be realized at least partially in the form of software units, whereas other units of these components can be purely hardware units. Such hardware units can be, for example, a radio frequency amplifier, an antenna facility of the radio frequency transmitter and/or of the radio frequency receiver, a gradient pulse generating facility of the output interface, an analog-to-digital converter of the radio frequency receiver and the like.

A realization, in particular of the components mentioned, largely through software has the advantage that conventionally used controllers of a magnetic resonance system can also easily be upgraded by way of a software update in order to operate in the manner according to the disclosure. The object is therefore also achieved with a computer program product which can be loaded directly into a transportable memory unit and/or provided via a network for transfer and so is loadable directly into a memory store of a programmable controller of the magnetic resonance system, having program portions in order to carry out all the steps of the method according to the disclosure in accordance with one of the embodiments described above when the program is executed by means of the controller. Such a computer program product can comprise, apart from the computer program, additional constituents, if relevant, such as for example, documentation and/or additional components including hardware components, for example, hardware keys (dongles, etc.) in order to use the software.

Stored on the computer-readable medium according to the disclosure are program portions that are configured to be read in and executed by a computer unit, in order to carry out all the steps of a method according to the disclosure in accordance with an embodiment described above when the program portions are executed by the computer unit.

For transport of parts of the controller and/or for storage on or in the controller, a computer-readable medium, for example a memory stick, a hard disk or other transportable or firmly installed data carrier can be used on which the program portions of the computer program which can be read in and executed by a computer unit are stored. For this purpose, the computer unit can have, for example, one or more cooperating microprocessors or the like.

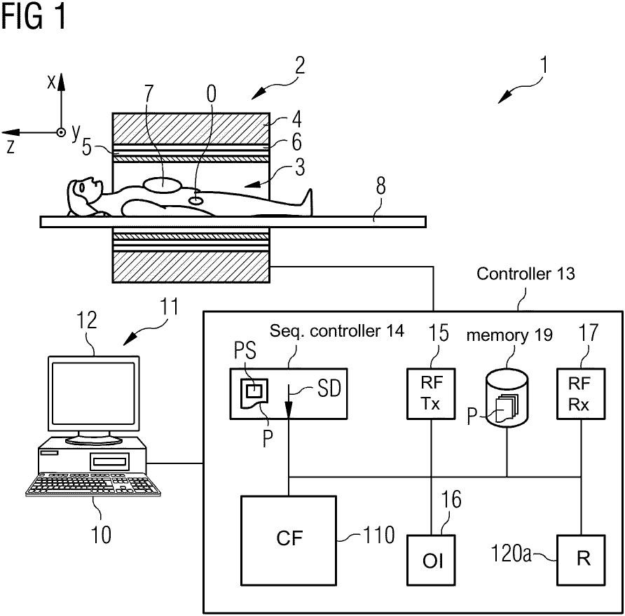

In the magnetic resonance system 1 shown in FIG. 1, what is shown is a magnetic resonance apparatus 2 with an examination region 3 designed as a patient tunnel into which an examination object can be fully introduced. The examination object in the present example is a patient who can be positioned by means of the patient positioning apparatus 8 relative to the magnetic resonance apparatus 2. In principle, however, the magnetic resonance apparatus 1 according to the disclosure can also comprise a different magnetic resonance system, for example, with laterally open, C-shaped housings. It is essential that the magnetic resonance apparatus 2 is configured to carry out magnetic resonance scans in order to be able to capture image data of the examination object.

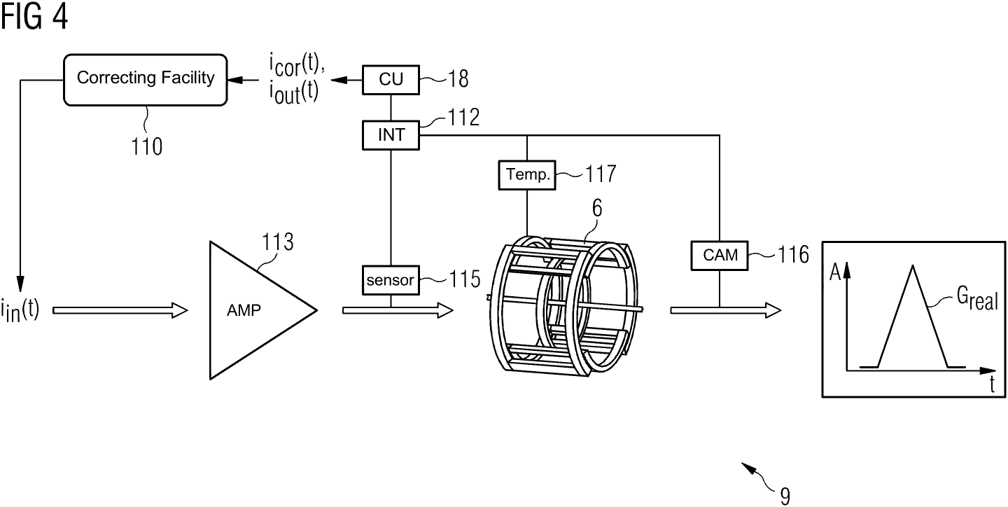

In an exemplary embodiment, the magnetic resonance apparatus 2 is equipped with a main field magnet system 4, at least one gradient coil 6 and a radio frequency transmitting antenna 5 and a radio frequency receiving antenna 7. In the exemplary embodiment shown, the radio frequency transmitting antenna 5 is a body coil firmly installed in the magnetic resonance apparatus 2. By contrast, the radio frequency receiving antenna 7 is one or more local coils arranged on the patient. In principle, however, the body coil can also be designed as radio frequency receiving antennae and the local coils can be designed as radio frequency transmitting antennae and/or have a corresponding functionality. The main field magnet system 4 is designed in this case to generate a main magnetic field in the longitudinal direction of the patient, i.e. along the longitudinal axis of the magnetic resonance apparatus 2 extending in the Z-direction. In an exemplary embodiment, the gradient system 9 (see FIG. 4) of the magnetic resonance apparatus 2 includes a plurality of individually controllable gradient coils 6 in order to be able to play out gradients in the X, Y or Z-directions independently of one another.

The magnetic resonance system 1 has a central controller 13 which is configured to control the magnetic resonance system 1. This central controller 13 can also comprise a sequence controller 14. With the sequential controller 14, the sequence of RF pulses and gradient pulses is controlled dependent upon a selected pulse sequence PS or a series of a plurality of pulse sequences PS for capturing image data of a relevant volume of the examination object, in particular, one or more slices of the volume region of interest in the context of a magnetic resonance scan. A pulse sequence PS of this type can be specified and parameterized within a scan or control protocol P. Typically, different control protocols P for different magnetic resonance scans are stored in a memory storage unit (memory) 19 and can be selected by an operator, and if needed, changed, and then used for carrying out the magnetic resonance scan. In the present case, the controller 13 contains a plurality of pulse sequences PS for the acquisition of raw data. In an exemplary embodiment, the controller 13 includes processing circuitry that is configured to perform one or more functions of the controller 13. In an exemplary embodiment, one or more components of the controller 13, such as the computing unit 18, includes processing circuitry that is configured to perform one or more respective functions and/or operations of the component(s).

For the output of individual RF pulses of a pulse sequence PS, the central controller 13 has a RF transmitting unit (transmitter) 15. The transmitter 15 generates and amplifies the RF pulses and transfers them via a signal connection and a suitable interface to the radio frequency transmitting antenna 5 (not shown in detail). For the control of the gradient coils 6 of the gradient system 9, in particular in order to switch or play out the gradient pulses suitably according to a pre-defined pulse sequence PS, the controller 13 has an output interface 16. By means of the output interface 16, for example, diffusion gradient pulses or spoiler gradient pulses can be applied. In the present case, the output interface 16 has a signal connection to a gradient coil 6 (see FIG. 4) of the gradient system 9 which generates corresponding magnetic field gradients in the examination region 3 dependent upon the applied gradient pulses. The sequence controller 14 communicates in a suitable manner, for example, by transmitting sequence control data SD, with the transmitter 15 and the output interface 16 for carrying out the pulse sequence PS.

The controller 13 also has a radio frequency (RF) receiving unit (receiver) 17 (also communicating in a suitable manner with the sequence controller 14), in order to receive magnetic resonance signals within a readout window pre-determined by way of the pulse sequence PS in a coordinated manner, by means of the radio frequency receiving antenna 7, and so to acquire the raw data.

The magnetic resonance system 1 can also have a reconstruction unit (reconstructor) 120a which is configured to reconstruct image data of the examination object dependent upon captured magnetic resonance signals. This reconstruction can take place on the basis of parameters which can be specified in the respective scan or control protocol P. The reconstructed image data can then be stored, for example, in the storage unit 19.

The correcting facility (pulse generator) 110 has a signal connection to the other components, in particular the output interface 16 and/or the sequence controller 14. Alternatively, the correcting facility 110 can also be configured as a part of the sequence controller 14. In an exemplary embodiment, the correcting facility 110 is configured to generate suitable gradient pulses g_{ref}(t) and to transfer them to the output interface 16 or the gradient coil 6. Given this, the correcting facility can be referred to as a pulse generator. It is conceivable that for this the correcting facility 110 comprises an amplifier 113 (see FIG. 4) of the gradient system 9 and specifies an input signal iᵢₙ(t) of the amplifier 113. Alternatively, the correcting facility 110 can also be present separately from the amplifier 113 and can initiate an emitting of gradient pulses g_{ref}(t) by means of a suitable signal connection. The correcting facility 110 is in particular configured to adjust an input signal iᵢₙ(t) of the amplifier 113 dependent upon an established output signal i_{cor}(t) and of a captured output signal iₒᵤt(t) of the amplifier 113 (see FIG. 4). Given this, the correcting facility can additionally or alternatively be referred to as a signal adjuster.

An operation of the central controller 13 can take place via a terminal 11 with an input unit 10 and a display unit 12. In an exemplary embodiment, the magnetic resonance system 1 can be controlled by an operator by means of the terminal 11. The display unit 12 can be configured to output captured image data of a magnetic resonance scan. The input unit 10 can be configured to parameterize and start magnetic resonance scans by means of the magnetic resonance system 1, possibly in combination with the display unit 12. This can comprise, in particular, a selection and/or modification of control protocols P and/or pulse sequences PS.

The magnetic resonance system 1 according to the disclosure and, in particular, the controller 13 can also have a plurality of further components which are not disclosed in detail here, but are typically present in such systems, such as for example, a network interface in order to connect the overall system to a network and to be able to exchange and/or process raw data and/or image data or parameter maps, but also further data such as patient-relevant data or control protocols.

How in detail, by way of a radiating-in of RF pulses and the emission of gradient pulses, suitable magnetic resonance signals are captured and therefrom image data or parameter maps can be reconstructed, is essentially known to a person skilled in the art. Similarly, the most varied of scan sequences, for example, EPI scan sequences or other scan sequences for generating image data, also diffusion-weighted image data, is known in principle to persons skilled in the art. This aspect is therefore not considered in detail below.

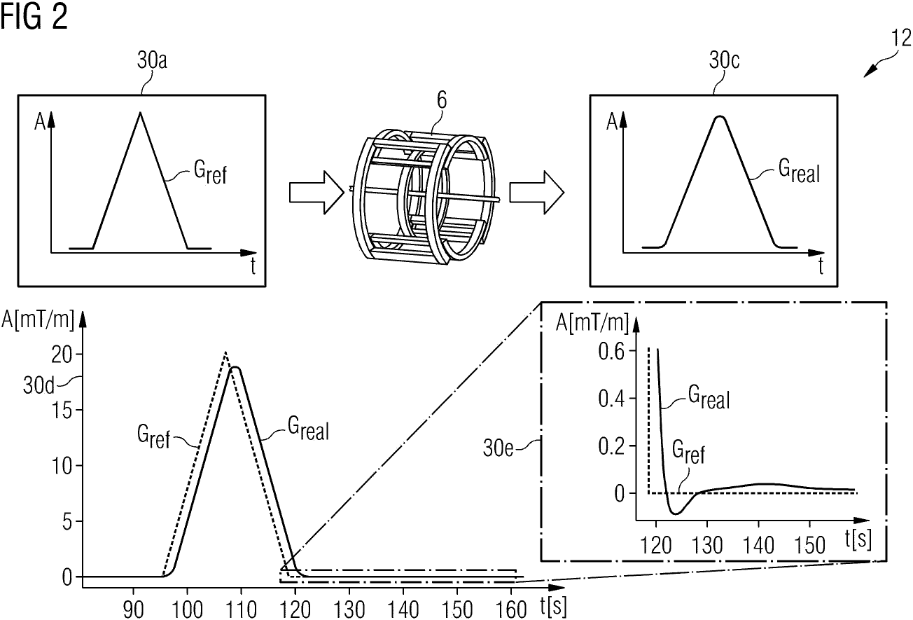

FIG. 2 shows a comparative representation 30 of emitted gradients G_{ref} and the actually played-out gradients Gᵣₑₐₗ of a pulse sequence of a magnetic resonance scan. The emitted gradients G_{ref} have field strength values which are stipulated by means of the controller 13 of the magnetic resonance system 1. By contrast, the real gradients Gᵣₑₐₗ represent the actually measured field strength values in an examination region. In a partial representation 30a, a graphical representation of an input gradient or output gradient G_{ref} is shown which is generated by the controller 13 of the magnetic resonance apparatus 2 and is transferred to the gradient coil 6 of the magnetic resonance apparatus 2 of the magnetic resonance system 1. The gradient Gᵣₑₐₗ actually played out by the gradient coil 6 is shown in a partial graphical representation 30c. The gradient G_{ref} sent out has a triangular form in the example shown in FIG. 2. Such a triangular form covers a relatively broad frequency range and therefore can map a response behavior of a gradient in the frequency domain relatively well. The actually played-out gradient Gᵣₑₐₗ has a gradient form which deviates from the emitted gradient G_{ref} due to the interference effects on the gradient system 9 as already described above, for example a non-linear behavior of an amplifier 113 (see FIG. 4), thermal changes in the hardware components, but also eddy currents and/or time-tuning and amplification errors.

In a partial graphical representation 30d, the two gradients G_{ref} and Gᵣₑₐₗ are shown together. As can be seen from the partial graphical representation 30e, the real gradient Gᵣₑₐₗ can also have a time offset relative to the emitted gradient G_{ref.}

A portion of the partial graphical representation 30d is shown enlarged in a partial graphical representation 30e. In the partial graphical representation 30e, it can be seen that the actual gradient Gᵣₑₐₗ or an amplitude A of the actual gradient Gᵣₑₐₗ at t = 122 s falls below the emitted gradient Gₙₒₘ and at approximately t = 130 s, assumes a higher magnitude value than the emitted gradient G_{ref} in order to coincide again with the emitted gradients on the zero line at values of t = 160 s.

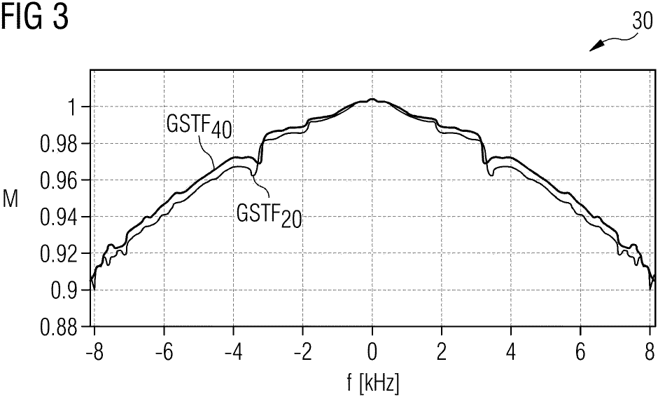

FIG. 3 shows a graphical representation 30 illustrating magnitudes M of two gradient system transfer functions GSTF at different reference temperatures. The gradient system transfer function GSTF is established in the present case on the basis of the quotient of the real gradient Gᵣₑₐₗ and the captured output signal Iₒᵤₜ of the amplifier 113. In FIG. 3, two gradient system transfer functions GSTF₂₀, GSTF₄₀ are illustrated for two different mean temperatures of the gradient system 9 of 20° C. and 40° C. The magnitudes M of GSTF₂₀ and GSTF₄₀ over frequency f are plotted in kHz. As can be seen in the graphical representation 30, the magnitude M of the gradient system transfer function at 40° C. is somewhat higher than at 20° C.

FIG. 4 shows a schematic representation of a sequence of the adjustment of the input signal iᵢₙ(t) of the amplifier 113 dependent upon the established output signal i_{cor}(t) and of the captured output signal iₒᵤt(t) of the amplifier 113. In an exemplary embodiment, the gradient system 9 of the magnetic resonance system 1 has a sensor 115 which is configured to capture a signal which correlates with the output signal iₒᵤt(t) of the amplifier 113. The sensor 115 can also be configured to transfer the signal by means of a signal connection to a computer unit (computer, computing device) 18 of the magnetic resonance system 1. In an exemplary embodiment, the computing unit 18 includes processing circuitry that is configured to perform one or more functions or operations of the computing unit 18. In an exemplary embodiment, the computing unit 18 is embodied in the controller 13, such as in the correcting facility 110.

The magnetic resonance system 1 further has a field camera 116 which is configured to capture the gradient sequence gᵣₑₐₗ(t) of the emitted gradient pulse g_{ref}(t) and to transfer it by means of a signal connection to the computer unit 18.

The computer unit 18 is accordingly configured to establish the gradient system transfer function GSTF dependent upon the real gradient sequence gᵣₑₐₗ(t) and the captured output signal iₒᵤt(t) of the amplifier 113. The computer unit 18 is herein also configured to establish the output signal i_{cor}(t) of the amplifier 113 with which the gradient system 9 provides the expected gradient sequence g_{ref}(t), dependent upon the gradient system transfer function GSTF. The output signal i_{cor}(t) of the amplifier 113 therefore represents, in particular, a target value of an output signal of the amplifier 113 at which interference effects occurring in the gradient system 9 are corrected or compensated for.

In the present example, the computer unit 18 transfers the output signal i_{cor}(t) of the amplifier 113 and the captured output signal iₒᵤt(t) of the amplifier 113 to the correcting facility 110. It is also conceivable that the computer unit 18 is integrated into the correcting facility 110. The correcting facility 110 is configured to adjust the input signal iᵢₙ(t) of the amplifier 113 dependent upon the output signal i_{cor}(t) of the amplifier 113 and the captured output signal iₒᵤt(t) of the amplifier 113. For this purpose, the correcting facility 110 can have, for example, a regulator, in particular an adaptive filter according to one of the embodiments described above.

In the example shown, the captured shape of the gradient Gᵣₑₐₗ(f) substantially matches the emitted or nominal gradient G_{ref}(f) (as shown in FIG. 2), since the correcting facility 110 corrects the interference effects in the gradient system 9 by adjusting the input signal iᵢₙ(t) of the amplifier 113. The sequence of the played-out gradients G_{ref}(f) substantially matches the expected or nominal gradients Gₙₒₘ(f).

In one embodiment, the temperature of the gradient coil 6 is captured by means of a temperature sensor 117 which is positioned on the gradient coil 6. It is conceivable that the temperature of the gradient coil 6 is transferred to the input interface 112 and is accessed by the computer unit 18 during the establishing of the output signal i_{cor}(t) of the amplifier 113.

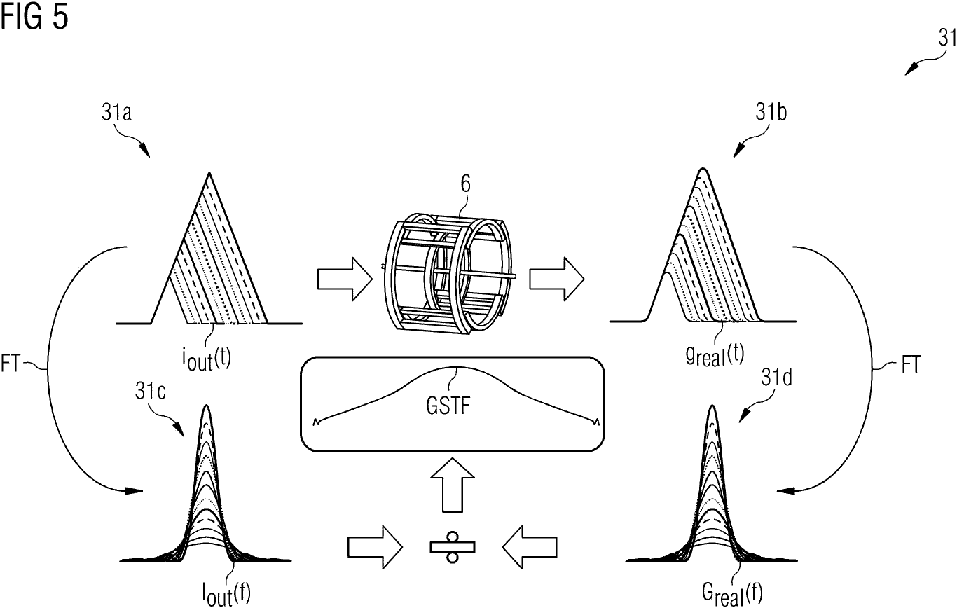

FIG. 5 shows a graphical representation 31 illustrating the principle of the establishing of a gradient system transfer function GSTF making use of a combination of twelve different triangular-shaped gradient pulses g_{ref},ᵢ(t). The gradient pulses g_{ref},ᵢ(t) each have an output signal i_{out,i}(t) that is output to the gradient coil 6 by the amplifier 113 by means of the output interface 16. In the partial graphical representation 31a, an ensemble of twelve triangular-shaped output signals i_{out,i}(t) of the amplifier 113 is shown with different line patterns (dashed, continuous, dotted). On passing through the gradient coil 6 of the gradient system 9 of the magnetic resonance apparatus 2, these generate actual gradient sequences g_{real,i}(t), which are shown in the partial graphical representation 31b. As shown in the partial graphical representation 31b, due to interference effects, the real gradient pulses g_{real,i}(t) deviate from the expected gradient sequences g_{nom,i}(t) which substantially match the emitted gradient pulses g_{ref,i}(t) (see also FIG. 2). The two partial graphical representations 31a and 31b are represented in the time domain. By contrast, the partial graphical representations 31c and 31d show the output signals I_{out,i}(f) of the amplifier 113 and the real gradients G_{real,i}(f) in the frequency domain. The output signals I_{out,i}(f) of the amplifier 113 and the real gradient G_{real,i}(f) each result by way of a Fourier transform FT of i_{out,i}(t) and g_{real,i}(t) from the time domain into the frequency domain. Furthermore, the graphical representation 31 shows a gradient system transfer function GSTF which is established by way of a division of the real gradients G_{real,i}(f) by the input signals I_{out,i}(f) of the amplifier 113. This behavior is symbolized by a division sign “÷” in FIG. 5.

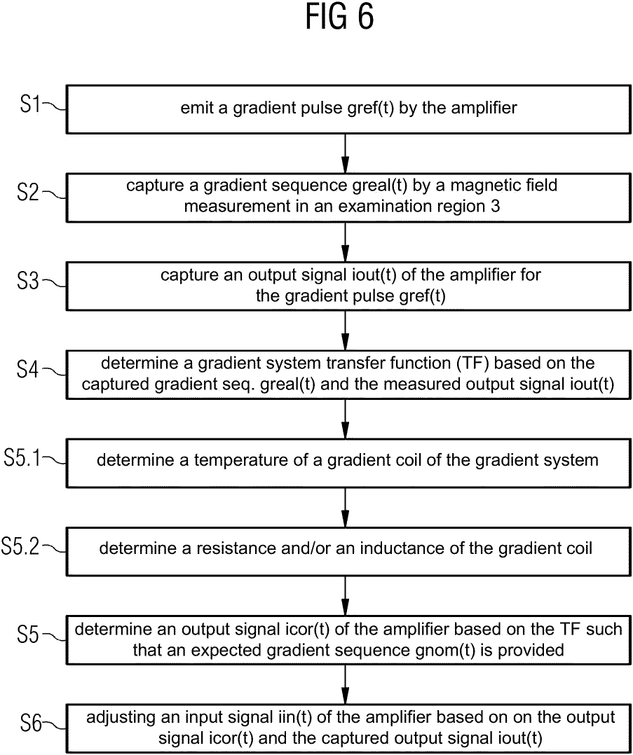

FIG. 6 shows a flow diagram of an embodiment of a method according to the disclosure for correcting an influence of an interference effect on a gradient system 9 of a magnetic resonance apparatus 2 during a magnetic resonance scan.

In a step S1 of the method according to the disclosure, a gradient pulse g_{ref}(t) is emitted by means of the amplifier 113. The gradient pulse can, in particular, represent a test gradient pulse or a regular gradient pulse during a magnetic resonance scan of a patient. The gradient pulse is provided by the output interface 16 of the amplifier 113 of the gradient system 9 and transferred to a gradient coil 6 of the gradient system 9 which provides the gradient pulse in the form of a magnetic field gradient in the examination region 3.

In one embodiment of the method according to the disclosure, the emitting of the gradient pulse g_{ref}(t) and the capturing of the gradient sequence gᵣₑₐₗ(t) take place in a repeating manner, in particular with a frequency of between one and five repetition intervals of the magnetic resonance scan.

In a step S2, a gradient sequence gᵣₑₐₗ(t) is captured by means of a magnetic field measurement in an examination region 3 of the magnetic resonance apparatus 2. The capturing of the gradient sequence can therein take place, in particular, by means of a magnetometer or a field camera 116, which transfers information and/or captured magnetic field data relating to the gradient sequence to the input interface 112 of the magnetic resonance apparatus 2, in particular the correcting facility 110. For this purpose, the magnetometer or the field camera 116 can be connected by means of a cable-bound or a wireless signal connection to the input interface 112.

In a further step S3, an output signal iₒᵤt(t) of the amplifier 113 for the gradient pulse g_{ref}(t) is captured. In an exemplary embodiment, the output signal of the amplifier 113 can be captured by means of a suitable sensor 115 such as, for example, a current probe, a Rogowski coil, a voltage measuring device, but also a measuring or current transformer. The sensor 115 can have, in particular, a signal connection to the input interface 112 in order to transfer an item of information and/or a measurement value relating to the output signal of the amplifier 113 to the controller 13 and/or the computer unit 18.

In a step S4, a gradient system transfer function (GSTF, GIRF) is established dependent upon the captured gradient sequence gᵣₑₐₗ(t) and the measured output signal iₒᵤt(t) of the amplifier 113. In an exemplary embodiment, the establishing of the gradient system transfer function takes place in accordance with equation (5) and the procedure described above (see FIG. 4).

In a further step S5, establishing an output signal i_{cor}(t) of the amplifier 113 with which the gradient system provides an expected gradient sequence gₙₒₘ(t) takes place, dependent upon the established gradient system transfer function (GSTF, GIRF). In an exemplary embodiment, for this purpose, the output signal i_{cor}(t) of the amplifier 113 is determined using equation (6).

$${i}_{c o r} ( t ) = {F}^{- 1} \left\{{G}_{n o m} ( f ) ⋅ G S T {F}^{- 1} \left(f\right)\right\}$$

The output signal i_{cor}(t) of the amplifier 113 therein represents an output signal which is needed to provide the expected nominal gradient pulse gₙₒₘ(t) in the examination region 3 of the magnetic resonance apparatus 2. The nominal gradient pulse gₙₒₘ(t) can substantially match the gradient sequence gᵣₑₐₗ(t), provided that no interference effects occur in the gradient system 9 or that interference effects occurring have to be corrected by means of the correcting facility 110 by adjusting the input signal iᵢₙ(t) of the amplifier 113. The term GSTF-¹ therein represents the inverse of the GSTF which is established dependent upon the captured gradient sequence gᵣₑₐₗ(t) and the captured output signal iₒᵤt(t) of the amplifier 113 in accordance with equation (5).

According to one embodiment, the establishing of the output signal i_{cor}(t) of the amplifier 113 takes place dependent upon a temperature of a gradient coil 6. For this purpose, the temperature of the gradient coil 6 can be integrated into equation (7) for the nominal output signal i_{cor}(t) of the amplifier 113. In an exemplary embodiment, for this purpose an expression is used for the temperature-dependent gradient system transfer function GSTF_{T}.

$${i}_{c o r}^{T} ( t ) = {F}^{- 1} \left\{{G}_{n o m} ( f ) ⋅ G S T {F}_{T}^{- 1} \left(f\right)\right\}$$

The temperature-dependence of the gradient system transfer function GSTF_{T} can be established, for example, by means of a linear model for a temperature-dependent change of the gradient system transfer function ΔGSTF in accordance with equation (8). Herein, Tₘₑₐₛ can be a matrix of measured temperature values at different time points Tₜ₌₀ to T_{t=N} and m can be a model parameter. This approach can comprise heuristic modelling in which the model parameters m are calibrated.

$$Δ G S T F = {T}_{m e a s} ⋅ m$$

It is, however, also conceivable that the temperature-dependency of the gradient system transfer function GSTF_{T} is established dependent upon a change in the resistance ΔR of the gradient coil 6. By way of the change in the resistance of the gradient coils 6 at different temperatures, the temperature-dependent change in the gradient system transfer function ΔGSTF can be determined by means of the following relationship (9):

$$Δ G S T F = f \left(Δ R \left(T\right)\right)$$

In an optional step S5.1, a temperature of a gradient coil 6 of the gradient system 9 is established. In an exemplary embodiment, therein the temperature of one or more gradient coils 6 of the gradient system 9 is captured by means of one or more temperature sensors and is transferred by means of a signal connection to the controller 13 and/or the computer unit 18 of the magnetic resonance system 1. The computer unit 18 is correspondingly configured to determine the output signal i_{cor}(t) of the amplifier 113 dependent upon the temperature of the gradient coil 6 by means of equation (7).

In one embodiment, the establishing of the temperature of the gradient coil 6 takes place dependent upon a model and/or an intelligent algorithm. It is conceivable that the establishing of the temperature of the gradient coil 6 takes place dependent upon a known operating characteristic of the amplifier 113. Furthermore, an analytical model, an empirical model and/or a simulation model of the amplifier 113, but also of the gradient coil 6 can be accessed for the establishing of the temperature of the gradient coil 6. Furthermore, information relating to a mechanical and/or electrical structure of the amplifier 113 and/or the gradient coil 6, an arrangement and/or an electrical connection of electronic components and/or a thermal conductivity and a heat capacity of materials used, can be used in the establishing of the temperature of the gradient coil 6.

In an alternative embodiment, the establishing of the temperature of the gradient coil 6 takes place dependent upon the captured output signal iₒᵤt(t) of the amplifier 113. Given knowledge of a current that is fed from the amplifier 113 into the gradient coil 6, the temperature of the gradient coil 6 can be determined very accurately dependent upon a simple analytical model of the gradient coil 6. In an exemplary embodiment, the establishing of the temperature of the gradient coil 6 takes place using a model and/or an intelligent algorithm by means of the computer unit 18 of the magnetic resonance system 1.

In an optional step S5.2, a resistance and/or an inductance of the gradient coil 6 of the gradient system 9 is established. The establishing of the resistance and/or the inductance can take place, in particular, according to an embodiment of the method according to the disclosure as described above. In one example, the temperature of the gradient coil 6 is established dependent upon a measurement resistor (shunt resistor) which is connected to a voltage measuring device. The resistance and/or the inductance of the gradient coil 6 can subsequently be accessed for an establishing of the temperature of the gradient coil 6 in the step S5.1.

In an optional step S6, an adjustment of an input signal iᵢₙ(t) of the amplifier 113 takes place dependent upon the established output signal i_{cor}(t) of the amplifier 113 and of the captured output signal iₒᵤt(t) of the amplifier 113. The adjustment of the input signal of the amplifier can take place directly or indirectly by means of a suitable regulator, in particular by means of an adaptive filter. In an exemplary embodiment, for the adjustment of the input signal of the amplifier, a correcting facility 110 is used (see FIG. 4). This can receive an output signal i_{cor}(t) of the amplifier 113, established in accordance with equation (6) or equation (7), from the computer unit 18 of the magnetic resonance system 1 and compare it in a quasi-continuous manner or in discrete time steps with the output signal iₒᵤt(t) of the amplifier 113 captured by means of the input interface 112. In the event of a deviation between the established output signal i_{cor}(t) and the captured output signal iₒᵤt(t) of the amplifier 113, the input signal iᵢₙ(t) of the amplifier 113 is adjusted by means of the correcting facility 110 so that the deviation is reduced. Thus, interference effects in the gradient system 6 can already be corrected by means of the correcting facility 110 when a gradient pulse is emitted.

In one embodiment, the adjustment of the input signal iᵢₙ(t) of the amplifier 113 takes place by means of an adaptive filter, in particular, a Volterra filter, a spline filter and/or a kernel filter. In an exemplary embodiment, the adaptive filter comprises a Volterra LMS method in which for a minimizing of the squares of errors, a least mean squares (LMS) algorithm is used.

It should again be noted that the detailed methods and constructions described in detail above are merely exemplary embodiments and that the basic principle can also be varied over a wide range by a person skilled in the art without departing from the field of the disclosure as defined in the claims. Furthermore, the method described is also not restricted to medical applications. For the sake of completeness, it should also be mentioned that the use of the indefinite article “a” or “an” does not preclude the relevant features from also being present plurally. Similarly, the expression “unit” does not preclude this consisting of a plurality of components which can possibly also be spatially distributed.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for correcting an influence of an interference effect on a gradient system of a magnetic resonance apparatus during a magnetic resonance scan, the method comprising:
emitting a gradient pulse using an amplifier of the gradient system;
performing a magnetic field measurement in an examination region of the magnetic resonance apparatus to capture a gradient sequence;
capturing, by a sensor, an output signal of the amplifier for the gradient pulse;
determining, by a computing device, a gradient system transfer function based on the captured gradient sequence and the captured output signal of the amplifier; and
determining an output signal of the amplifier with which the gradient system is configured to provide an expected gradient sequence based on the established gradient system transfer function.

2. The method as claimed in claim 1, wherein the emitting of the gradient pulse and the capturing of the gradient sequence is repeatedly performed.

3. The method as claimed in claim 1, wherein the emitting of the gradient pulse and the capturing of the gradient sequence is repeatedly performed with a frequency of between one and five repetition intervals of a pulse sequence of the magnetic resonance scan.

4. The method as claimed in claim 1, further comprising:
determining a temperature of a gradient coil of the gradient system,
wherein the determining of the output signal of the amplifier is based on the temperature of the gradient coil.

5. The method as claimed in claim 4, further comprising:
determining a resistance and/or an inductance of the gradient coil of the gradient system, wherein the determination of the temperature of the gradient coil is based on the resistance and/or the inductance of the gradient coil.

6. The method as claimed in claim 4, wherein the determination of the temperature of the gradient coil is based on a model and/or an intelligent algorithm.

7. The method as claimed in claim 4, wherein the determination of the temperature of the gradient coil is based on the captured output signal of the amplifier.

8. The method as claimed in claim 1, further comprising:
adjusting an input signal of the amplifier based on the determined output signal of the amplifier and of the captured output signal of the amplifier.

9. The method as claimed in claim 8, wherein the input signal of the amplifier is adjusted using an adaptive filter.

10. The method as claimed in claim 9, wherein the adaptive filter is a Volterra filter, a spline filter and/or a kernel filter.

11. The method as claimed in claim 1, wherein the emission of the gradient pulse comprises an emission of a plurality of gradient pulses.

12. The method as claimed in claim 11, wherein the plurality of gradient pulses cover a frequency spectrum of between -20 kHz and +20 kHz.

13. The method as claimed in claim 11, wherein the plurality of gradient pulses cover a frequency spectrum of between -10 kHz and +10 kHz.

14. A computer program product, embodied on a non-transitory computer readable medium, which includes a computer program that can be loadable into a memory of a controller of a magnetic resonance apparatus, that when executed, causes the controller to perform the method of claim 1.

15. A non-transitory computer-readable storage medium with an executable program stored thereon, that when executed, instructs a processor to perform the method of claim 1.

16. A correcting facility comprising:
an output interface configured to emit at least one gradient pulse;
an input interface configured to capture a gradient sequence and an output signal of an amplifier for the gradient pulse;
a computing device configured to:
establish a gradient system transfer function and an output signal of the amplifier based on the captured gradient sequence and the captured output signal of the amplifier, and
adjust an input signal of the amplifier based on the established output signal of the amplifier and the captured output signal of the amplifier.

17. A magnetic resonance apparatus comprising:
a magnetic resonance scanner; and
the correcting facility of claim 16,
wherein the correcting facility is configured to adjust the input signal of the amplifier during a magnetic resonance scan of an examination object by the magnetic resonance scanner to provide an expected gradient sequence.

18. The magnetic resonance apparatus of claim 17, wherein:
the magnetic resonance scanner comprises: a main field magnet system, a radio frequency transmitting antenna, a gradient system, and a radio frequency receiving antenna; and
the magnetic resonance apparatus further comprises a controller including the correcting facility, the controller being configured to control the main field magnet system, the radio frequency transmitting antenna, the gradient system and the radio frequency receiving antenna.
